(19) United States
(12) Patent Application Publication
(10) Pub. No.: US 2025/0136741 A1
(43) Pub. Date: May 1, 2025

(54) THERMOSETTING RESIN COMPOSITION, RESIN SHEET, METAL FOIL WITH RESIN, METAL-CLAD LAMINATE, AND PRINTED WIRING BOARD

(71) Applicant: Panasonic Intellectual Property Management Co., Ltd., Osaka (JP)

(72) Inventors: Yuji YAMADA, Osaka (JP); Eiichiro SAITO, Osaka (JP); Hiroyuki FUJISAWA, Fukushima (JP); Takahiro YAMADA, Fukushima (JP)

(73) Assignee: Panasonic Intellectual Property Management Co., Ltd., Osaka (JP)

(21) Appl. No.: 18/703,589

(22) PCT Filed: Oct. 17, 2022
(86) PCT No.: PCT/JP2022/038564

§ 371 Date: Nov. 20, 2024

(30) Foreign Application Priority Data
Oct. 25, 2021 (JP) 2021-174191

(51) Int. Cl. C08F 290/06; B32B 15/08; C08F 290/04; C08K 3/36; C08K 5/3415; C08K 9/04

(52) U.S. Cl. CPC C08F 290/062; B32B 15/08; C08F 290/048; C08K 3/36; C08K 5/3415; C08K 9/04; B32B 2307/102; B32B 2457/08; C08F 2810/40

(57) ABSTRACT

The present disclosure provides a thermosetting resin composition contributing to reducing the elastic modulus of a cured product and increasing the flexibility thereof while reducing the chances of causing a decline in the heat resistance of the cured product. A thermosetting resin composition contains: a maleimide compound (A) having at least two maleimide groups in one molecule; a compound (B) having, at either or both of terminals thereof, a substituent with an ethylenic unsaturated bond and having a polyphenylene ether skeleton; and an inorganic filler (C). The compound (B) includes a compound (B1) having a butadiene-derived structural unit.

### TECHNICAL FIELD

The present disclosure generally relates to a thermosetting resin composition, a resin sheet, a sheet of metal foil with resin, a metal-clad laminate, and a printed wiring board. More particularly, the present disclosure relates to a thermosetting resin composition containing a compound having a polyphenylene ether skeleton, a resin sheet and a sheet of metal foil with resin, each containing an uncured or semi-cured product of the thermosetting resin composition, and a metal-clad laminate and a printed wiring board, each containing a cured product of the thermosetting resin composition.

### BACKGROUND ART

Patent Literature 1 discloses, as a material for an insulating layer of a printed wiring board, a thermosetting adhesive composition. The composition of Patent Literature 1 contains, at a predetermined ratio: a vinyl compound having a polyphenylene ether skeleton; a maleimide resin having two or more maleimide groups; and an elastomer composed mainly of a polyphenylene skeleton and serving as a copolymer of a polyolefin block and a polystyrene block. Patent Literature 1 describes that an insulating layer made of this thermosetting adhesive composition has a low dielectric constant and a low dielectric loss tangent, exhibits excellent adhesive strength to an LCP film and copper foil, and has excellent heat resistance.

### CITATION LIST

### Patent Literature

Patent Literature 1: WO 2016/117554 A1

### SUMMARY OF INVENTION

The problem to be overcome by the present disclosure is to provide a thermosetting resin composition contributing to reducing the elastic modulus of a cured product and increasing the flexibility thereof while reducing the chances of causing a decline in the heat resistance of the cured product, a resin sheet and sheet of metal foil with resin each containing an uncured product or a semi-cured product of the thermosetting resin composition, and a metal-clad laminate and a printed wiring board each containing a cured product of the thermosetting resin composition.

A thermosetting resin composition according to an aspect of the present disclosure contains: a maleimide compound (A) having at least two maleimide groups in one molecule; a compound (B) having, at either or both of terminals thereof, a substituent with an ethylenic unsaturated bond and having a polyphenylene ether skeleton; and an inorganic filler (C). The compound (B) includes a compound (B1) having a butadiene-derived structural unit.

A resin sheet according to another aspect of the present disclosure contains an uncured product or semi-cured product of the above-described thermosetting resin composition.

A sheet of metal foil with resin according to still another aspect of the present disclosure includes a sheet of metal foil, and a resin layer laid on the sheet of metal foil. The resin layer contains an uncured product or semi-cured product of the above-described thermosetting resin composition.

A metal-clad laminate according to yet another aspect of the present disclosure includes: an insulating layer; and a sheet of metal foil laid on the insulating layer. The insulating layer contains a cured product of the above-described thermosetting resin composition.

A printed wiring board according to yet another aspect of the present disclosure includes an insulating layer and conductor wiring. The insulating layer contains a cured product of the above-described thermosetting resin composition.

### DESCRIPTION OF EMBODIMENTS

The present inventors discovered, based on the results of extensive research, that adding not only a compound having a polyphenylene ether skeleton but also an inorganic filler to a composition would increase the chances of causing an increase in the elastic modulus of a cured product of the composition and a decrease in the flexibility thereof, thus making it difficult to form the composition into a film shape. As taught by Patent Literature 1 (WO 2016/117554 A1), further adding an elastomer to the composition certainly enables reducing the elastic modulus of the cured product and increasing the flexibility thereof. In that case, however, the low degree of compatibility between the elastomer and a maleimide compound such as a maleimide resin is likely to cause a decrease in the homogeneity of the composition and a decline in the heat resistance of the cured product.

To overcome this problem, the present disclosure provides a thermosetting resin composition contributing to reducing the elastic modulus of the cured product and increasing the flexibility thereof while reducing the chances of causing a decline in the heat resistance of the cured product.

An exemplary embodiment of the present disclosure will now be described. Note that the exemplary embodiment to be described below is only an exemplary one of various embodiments of the present disclosure and should not be construed as limiting. Rather, the exemplary embodiment may be readily modified in various manners depending on a design choice or any other factor without departing from the scope of the present disclosure.

A thermosetting resin composition (hereinafter also referred to as “composition (X)”) according to this embodiment contains: a maleimide compound (A) having at least two maleimide groups in one molecule; a compound (B) having, at either or both of terminals thereof, a substituent with an ethylenic unsaturated bond and having a polyphenylene ether skeleton; and an inorganic filler (C). The compound (B) includes a compound (B1) having a butadiene residue. That is to say, the compound (B1) has, at either or both of its terminals, a substituent with an ethylenic unsaturated bond and has a polyphenylene ether skeleton and a butadiene residue. As used herein, the “butadiene residue” is a butadiene-derived structural unit. The butadiene-derived structural unit has at least one of a structural unit expressed by the following formula (P) or a structural unit expressed by the following formula (Q). That is to say, the compound (B1) has at least one of the structural unit expressed by the following formula (P) or the structural unit expressed by the following formula (Q):

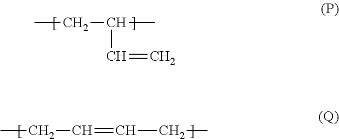

This embodiment may contribute to reducing the elastic modulus of a cured product obtained by curing the composition (X) and increasing the flexibility thereof. This is presumably because incorporating a butadiene residue derived from the compound (B1) into a resin matrix produced by the reaction between the maleimide compound (A) and the compound (B) would increase the flexibility of the resin matrix itself. In addition, compared to attempting to reduce the elastic modulus of the cured product and increase the flexibility thereof using only an elastomer, for example, the compound (B1) according to this embodiment is less likely to impede the homogeneity of the composition (X) or cause a decrease in the glass transition temperature of the cured product.

Thus, the composition (X) contains the maleimide compound (A), the compound (B) having the polyphenylene ether skeleton, and the inorganic filler (C) and still contributes to reducing the elastic modulus of the cured product and increasing the flexibility thereof while reducing the chances of causing a decline in the heat resistance of the cured product.

This composition (X) may be used to manufacture, for example, a resin sheet, a sheet of metal foil with resin, a metal-clad laminate, or a printed wiring board, all of which will be described later. Note that these are only exemplary uses of the composition (X) and should not be construed as limiting. Rather, the composition (X) may also be used for any of various other applications in which its properties may be made use of.

The composition (X) will be described in further detail.

In this embodiment, the composition (X) contains the maleimide compound (A) and the compound (B), thus allowing a cured product of the composition (X) to have a low dielectric constant and a low dielectric loss tangent. This may improve the radio frequency characteristics of a metal-clad laminate and printed wiring board, each including a cured product of the composition (X).

The maleimide compound (A) is a compound having at least two maleimide groups in one molecule, as described above. The maleimide compound (A) may increase the heat resistance of the cured product. The number of the maleimide groups per molecule of the maleimide compound (A) has only to be at least two but may be equal to or greater than 2 and equal to or less than 10 and is preferably equal to or greater than 2 and equal to or less than 6.

The maleimide compound (A) preferably contains an oligomer (maleimide oligomer). This makes it significantly easier for the cured product to have a lower dielectric constant and a lower dielectric loss tangent. The maleimide oligomer may have, for example, a weight average molecular weight equal to or greater than 500 and equal to or less than 2000, for example. Note that the weight average molecular weight is value calculated by converting the result of measurement of gel permeation chromatography (GPC) into an equivalent polystyrene weight.

The maleimide oligomer may contain, for example, a compound having the structure expressed by the following formula (1). This makes it significantly easier for the cured product to have a lower dielectric constant and a lower dielectric loss tangent. This is presumably because this compound has a rigid structure and a low degree of polarity. In this formula (1), n in one molecule represents the number of repeating units and may fall, for example, within the range from 1 to 5.

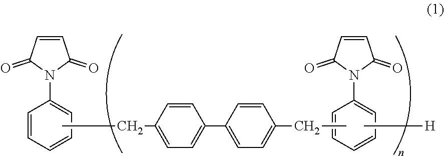

Specific examples of the maleimide oligomer include MIR3000 (product number of a product manufactured by Nippon Kayaku Co., Ltd.

Note that this is only an exemplary structure for the maleimide oligomer and should not be construed as limiting.

The maleimide compound (A) may contain a monomer (maleimide monomer). If the maleimide compound contains a maleimide monomer, the maleimide monomer includes at least one selected from the group consisting of, for example, 4,4′-diphenylmethanebismaleimide, m-phenylenebismaleimide, bisphenol A diphenyletherbismaleimide, 3,3′-dimethyl-5,5′-diethyl-4,4′-diphenylmethanebismaleimide, 4-methyl-1,3-phenylenebismaleimide, and 1,6-bismaleimide-(2,2,4-trimethyl) hexane. More specific examples of maleimide monomers include BMI-689 and BMI-3000 (product names) manufactured by Designer Molecules Inc.

Next, the compound (B) will be described. The compound (B) has, at either or both of its terminals, a substituent (hereinafter referred to as a “substituent (S)”) with an ethylenic unsaturated bond and has a polyphenylene ether skeleton as described above.

The substituent (S) may be, for example, a substituent (S1) expressed by the following formula (2), or a substituent (S2) expressed by the following formula (3):

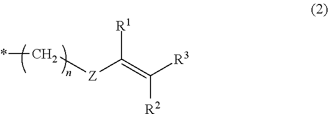

In the formula (2), n is an integer falling within the range from 0 to 10, Z is an arylene group, and R¹ to R³ are each independently either a hydrogen atom or an alkyl group. Note that if n is zero in the formula (2), then Z is directly bonded to the terminal of the compound (B).

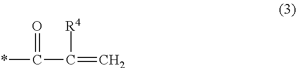

In the formula (3), R⁴ is either a hydrogen atom or an alkyl group.

As for the substituent (S1), specific examples of Z in the formula (2) include a divalent monocyclic aromatic group such as a phenylene group and a divalent polycyclic aromatic group such as a naphthylene group. At least one hydrogen atom in the aromatic ring in Z may be replaced with an alkenyl group, an alkynyl group, a formyl group, an alkylcarbonyl group, an alkenylcarbonyl group, or an alkynylcarbonyl group.

The substituent (S1) preferably has a vinylbenzyl group as at least a part thereof. The substituent (S1) may be, for example, a substituent expressed by the following formula (4) or the following formula (5):

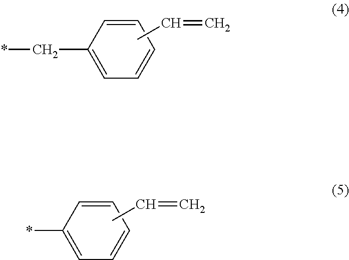

The polyphenylene ether skeleton may have, for example, a structure expressed by the following formula (6):

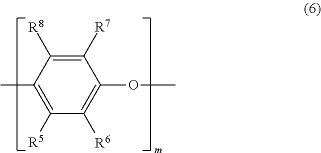

In the formula (6), m is the number of repeating units, which may be a number falling within the range from 1-50. R⁵ to R⁸ each independently represent a hydrogen atom, an alkyl group, an alkenyl group, an alkynyl group, a formyl group, an alkylcarbonyl group, an alkenylcarbonyl group, or an alkynylcarbonyl group, for example.

The alkyl group preferably has 1 to 18 carbon atoms, and more preferably has 1 to 10 carbon atoms. More specifically, the alkyl group may be, for example, a methyl group, an ethyl group, a propyl group, a hexyl group, or a decyl group. The alkenyl group preferably has 2 to 18 carbon atoms, and more preferably has 2 to 10 carbon atoms. More specifically, the alkenyl group may be, for example, a vinyl group, an allyl group, or a 3-butenyl group. The alkynyl group preferably has 2 to 18 carbon atoms, and more preferably has 2 to 10 carbon atoms. More specifically, the alkynyl group may be, for example, an ethynyl group, or a prop-2-yn-1-yl group (propargyl group). The alkylcarbonyl group preferably has 2 to 18 carbon atoms, and more preferably has 2 to 10 carbon atoms. More specifically, the alkylcarbonyl group may be, for example, an acetyl group, a propionyl group, a butyryl group, an isobutyryl group, a pivaloyl group, a hexanoyl group, an octanoyl group, or a cyclohexylcarbonyl group. The alkenylcarbonyl group preferably has 3 to 18 carbon atoms, and more preferably has 3 to 10 carbon atoms. More specifically, the alkenylcarbonyl group may be, for example, an acryloyl group, a methacryloyl group, or a crotonoyl group. The alkynylcarbonyl group preferably has 3 to 18 carbon atoms, and more preferably has 3 to 10 carbon atoms. More specifically, the alkynylcarbonyl group may be, for example, a propioloyl group.

Particularly preferably, R⁵ to R⁸ are each independently a hydrogen atom or an alkyl group.

The compound (B) includes a compound (B1) having a butadiene residue as described above. That is to say, the compound (B1) is a compound having, at either or both of its terminals, the substituent (S) and having the polyphenylene ether skeleton and the butadiene residue. The compound (B1) may have, for example, a plurality of polyphenylene ether skeletons and a plurality of butadiene residues in one molecule and have a structure in which the polyphenylene ether skeletons and the butadiene residues are alternately linked together.

Optionally, the compound (B) may include not only the compound (B1) but also a compound (B2) having no butadiene residues. The compound (B2) is a compound having, for example, a polyphenylene ether skeleton and the substituent (S) bonded to at least one terminal of the polyphenylene ether skeleton. Letting the compound (B) include the compound (B2) may further increase the degree of compatibility between the compound (B) and the maleimide compound (A), further reduce the dielectric constant and dielectric loss tangent of the cured product, and further increase the heat resistance of the cured product. The compound (B2) may be synthesized by, for example, introducing the substituent (S) by modifying the terminal(s) of the polyphenylene ether.

The compound (B1) preferably has a weight average molecular weight equal to or greater than 50,000 and equal to or less than 100,000. Setting the weight average molecular weight at a value equal to or greater than 50,000 may cause a significant increase in the flexibility of the cured product. Setting the weight average molecular weight at a value equal to or less than 100,000 reduces the chances of the compound (B1) causing a decrease in the glass transition temperature of the cured product, thus allowing the cured product to maintain sufficient heat resistance. In addition, this also allows the sheet of copper foil to maintain sufficiently high adhesion to an insulating layer including the cured product, for example. The weight average molecular weight is more preferably equal to or greater than 60,000 and even more preferably equal to or greater than 70,000. Meanwhile, the weight average molecular weight is more preferably equal to or less than 90,000 and even more preferably equal to or less than 80,000. Note that the weight average molecular weight is value calculated by converting the result of measurement of gel permeation chromatography (GPC) into an equivalent polystyrene weight.

The compound (B2) preferably has a weight average molecular weight equal to or greater than 500 and equal to or less than 5,000. This allows the compound (B2) to impart excellent dielectric properties to the cured product and may cause an increase in the heat resistance and moldability of the cured product. In addition, setting the weight average molecular weight at a value equal to or greater than 500 causes a decrease in the glass transition temperature of the cured product, thus allowing the cured product to have good heat resistance. Furthermore, setting the weight average molecular weight at a value equal to or less than 5,000 causes an increase in the solubility of the compound (B2) in a solvent, thus reducing the chances of causing a decline in the storage stability of the composition (X). Besides, this also reduces the chances of the compound (B2) causing an increase in the viscosity of the composition (X), thus allowing the composition (X) to have good moldability. The compound (B2) more preferably has a weight average molecular weight equal to or greater than 800 and even more preferably has a weight average molecular weight equal to or greater than 1,000. Meanwhile, the compound (B2) more preferably has a weight average molecular weight equal to or less than 4,000 and even more preferably has a weight average molecular weight equal to or less than 3,000. Note that the weight average molecular weight is value calculated by converting the result of measurement of gel permeation chromatography (GPC) into an equivalent polystyrene weight.

The percentage of the compound (A) to the composition (X) is preferably equal to or greater than 10 parts by mass and equal to or less than 60 parts by mass with respect to 100 parts by mass in total of the compound (A) and the compound (B), for example (or the total of the compound (A), the compound (B), and a reactive compound (D) (to be described later) if the composition (X) contains the reactive compound (D)). Setting this percentage at a value equal to or greater than 10 parts by mass causes a more significant increase in the heat resistance of the cured product and a more significant decrease in the dielectric constant and dielectric loss tangent thereof. Meanwhile, setting this percentage at a value equal to or less than 60 parts by mass may reduce the chances of causing a decrease in the glass transition temperature of the cured product. This percentage is more preferably equal to or greater than 20 parts by mass and even more preferably equal to or greater than 25 parts by mass. This percentage is more preferably equal to or less than 50 parts by mass and even more preferably equal to or less than 40 parts by mass.

The percentage of the compound (B1) to the composition (X) is preferably equal to or greater than 5 parts by mass and equal to or less than 30 parts by mass with respect to 100 parts by mass in total of the compound (A) and the compound (B), for example (or the total of the compound (A), the compound (B), and the reactive compound (D) (to be described later) if the composition (X) contains the reactive compound (D)). Setting this percentage at a value equal to or greater than 5 parts by mass causes a more significant decrease in the elastic modulus of the cured product and a more significant increase in the flexibility thereof. Meanwhile, setting this percentage at a value equal to or less than 30 parts by mass may reduce the chances of causing a decline in the machinability of the cured product. This percentage is more preferably equal to or greater than 10 parts by mass and even more preferably equal to or greater than 15 parts by mass. This percentage is more preferably equal to or less than 25 parts by mass and even more preferably equal to or less than 20 parts by mass.

The percentage of the compound (B2) to the composition (X) is preferably equal to or greater than 10 parts by mass and equal to or less than 70 parts by mass with respect to 100 parts by mass in total of the compound (A) and the compound (B), for example (or the total of the compound (A), the compound (B), and the reactive compound (D) (to be described later) if the composition (X) contains the reactive compound (D)). Setting this percentage at a value equal to or greater than 10 parts by mass causes a more significant increase in the heat resistance of the cured product and a more significant decrease in the dielectric constant and dielectric loss tangent thereof. Meanwhile, setting this percentage at a value equal to or less than 70 parts by mass may reduce the chances of causing a decrease in the glass transition temperature of the cured product. This percentage is more preferably equal to or greater than 20 parts by mass and even more preferably equal to or greater than 30 parts by mass. This percentage is more preferably equal to or less than 50 parts by mass and even more preferably equal to or less than 40 parts by mass.

Furthermore, the percentage of the compound (B) to the composition (X) is preferably equal to or greater than 15 parts by mass and equal to or less than 80 parts by mass with respect to 100 parts by mass in total of the compound (A) and the compound (B), for example (or the total of the compound (A), the compound (B), and the reactive compound (D) (to be described later) if the composition (X) contains the reactive compound (D)).

Next, the inorganic filler (C) will be described. The inorganic filler (C) may contribute to lowering the dielectric constant and dielectric loss tangent of the cured product. In addition, the inorganic filler (C) may also contribute to improving the heat resistance, flame retardance, and toughness of the cured product and reducing the coefficient of thermal expansion thereof.

Examples of the inorganic filler (C) include at least one material selected from the group consisting of silica, alumina, talc, aluminum hydroxide, magnesium hydroxide, titanium oxide, mica, aluminum borate, barium sulfate, boron nitride, forsterite, zinc oxide, magnesium oxide, and calcium carbonate. Note that these are only exemplary materials that may be contained in the inorganic filler (C) and should not be construed as limiting. Optionally, the inorganic filler (C) may be subjected to appropriate surface treatment.

The inorganic filler (C) is preferably surface-treated with a surface treatment agent including a phenylamino group. The inorganic filler (C) particularly preferably contains a silica surface-treated with a surface treatment agent including a phenylamino group. The surface treatment agent including a phenylamino group may be, for example, phenylamino silane. This may cause a significant increase in the adhesion between an insulating layer, for example, including the cured product and the sheet of copper foil. This result is presumably obtained due to the high polarity of a phenylamino group introduced onto the surface of a particle of the inorganic filler (C) through the surface treatment using phenylamino silane. In addition, the inorganic filler (C) surface-treated with the phenylamino silane also reduces the chances of causing an increase in the viscosity of the composition (X) and a decrease in the flowability of a semi-cured product of the composition (X), and therefore, reduces the chances of causing a decline in the moldability of the composition (X) and a semi-cured product thereof. This is presumably because interaction is less likely to occur between the phenylamino group, the compound (A), and the compound (B).

Optionally, the inorganic filler (C) may be surface-treated with an appropriate surface treatment agent other than the surface treatment agent having a phenylamino group. For example, the inorganic filler (C) may be surface-treated with a surface treatment agent having a polymerizable unsaturated bond. This allows the polymerizable unsaturated bond of the inorganic filler (C) to react with each of the compound (A) and the compound (B), thus allowing the cured product to have an increased crosslinking density. Therefore, even if the cured product of the composition (X) is left at high temperatures, the dielectric loss tangent of the cured product is unlikely to increase. That is to say, the dielectric loss tangent of the insulating layer made of the composition (X) is less likely to increase at high temperatures. The polymerizable unsaturated bond includes, for example, at least one selected from the group consisting of vinyl groups, allyl groups, methacrylic groups, styryl groups, acryloyl groups, methacryloyl groups, and maleimide groups. A surface treatment agent having a polymerizable unsaturated bond may be, but does not have to be, a silane coupling agent having a polymerizable unsaturated bond.

The percentage of the inorganic filler (C) to the composition (X) is preferably equal to or greater than 100 parts by mass and equal to or less than 400 parts by mass with respect to 100 parts by mass in total of the compound (A) and the compound (B), for example (or the total of the compound (A), the compound (B), and the reactive compound (D) (to be described later) if the composition (X) contains the reactive compound (D)). Setting this percentage at a value equal to or greater than 100 parts by mass allows the inorganic filler (C) to contribute to improving the properties of the cured product. Meanwhile, setting this percentage at a value equal to or less than 400 parts by mass may reduce the chances of the inorganic filler (C) causing a decline in the moldability of the composition (X) and the elasticity and flexibility of the cured product. This percentage is more preferably equal to or greater than 150 parts by mass and even more preferably equal to or greater than 200 parts by mass. This percentage is more preferably equal to or less than 350 parts by mass and even more preferably equal to or less than 300 parts by mass.

The composition (X) may contain, other than the compound (A) and the compound (B), a reactive compound (D) reactive with both the compound (A) and the compound (B). The reactive compound (D) preferably has at least one polymerizable unsaturated group selected from the group consisting of, for example, vinyl groups, allyl groups, methacrylic groups, styryl groups, and (meth)acrylic groups. In particular, the reactive compound (D) preferably contains at least one of an allyl compound as a compound having an allyl group and a (meth)acrylate compound as a compound having a (meth)acrylic group. Adding the reactive compound (D) to the composition (X) allows the physical properties of the composition (X) and the cured product thereof to be controlled by selecting the components contained in the reactive compound (D). For example, if the reactive compound (D) contains a monofunctional compound having one polymerizable unsaturated bond, the monofunctional compound may reduce the melt viscosity of the composition (X) and thereby improve the moldability thereof. Also, if the reactive compound (D) contains a polyfunctional compound having a plurality of polymerizable unsaturated bonds, the polyfunctional compound may increase the crosslink density of the cured product. As a result, the polyfunctional compound may contribute to improving the toughness of the cured product, increasing the glass transition temperature, and thereby increasing the heat resistance, reducing the coefficient of linear expansion, and improving adhesiveness. If the reactive compound (D) contains a polyfunctional compound, the polyfunctional compound preferably contains at least one selected from the group consisting of, for example, divinylbenzene, trivinylcyclohexane, diallyl bisphenol A (DABPA), triallyl isocyanurate (TAIC), dicyclopentadiene dimethanol dimethacrylate, nonanediol dimethacrylate, and tricyclodecane dimethanol dimethacrylate (DCP). In particular, the polyfunctional compound preferably includes at least one selected from the group consisting of, for example, allyl compounds having two or more allyl groups, such as diallyl bisphenol A (DABPA) and triallyl isocyanurate (TAIC), and (meth)acrylate compounds having two or more (meth)acrylic groups such as dicyclopentadiene dimethanol dimethacrylate, nonanediol dimethacrylate, and tricyclodecanedimethanol dimethacrylate (DCP). This allows the cured product of the composition (X) to have increased heat resistance.

Optionally, the composition (X) may further contain a polymerization initiator. The polymerization initiator may be, for example, a thermo-radical polymerization initiator. The thermo-radical polymerization initiator may promote the curing reaction of the composition (X) when the composition (X) is heated. Note that if the composition (X) contains a component that may produce an activate species when heated, then the composition (X) may contain no thermo-radical polymerization initiators.

The thermo-radical polymerization initiator preferably contains a peroxide. This may promote the curing reaction of the composition (X) particularly significantly, shorten the time it takes to have the composition (X) cured, and contribute to improving the physical properties of the cured product by, for example, reducing the coefficient of linear expansion, increasing the glass transition temperature, and improving the solder heat resistance. The peroxide contains at least one component selected from the group consisting of, for example, α,α′-bis(t-butylperoxy-m-isopropyl) benzene, 2,5-dimethyl-2,5-di(t-butylperoxy)-3-hexine, benzoyl peroxide, 3,3′,5,5′-tetramethyl-1,4-diphenoquinone, chloranil, 2,4,6-tri-t-butylphenoxyl, t-butylperoxy isopropyl monocarbonate, t-amylperoxy neodecanoate, t-amylperoxy pivalate, t-amylperoxy-2-ethyl hexanoate, t-amylperoxy normal octoate, t-amylperoxy acetate, t-amylperoxy isononanoate, t-amylperoxy benzoate, t-amylperoxyisopropyl carbonate, di-t-amyl peroxide, 1,1-di (t-amylperoxy) cyclohexane, and azobisisobutyronitrile.

Note that these are only exemplary components that may be contained in the thermo-radical polymerization initiator and should not be construed as limiting.

The content of the thermo-radical polymerization initiator may be, but does not have to be, equal to or greater than 0.1 parts by mass and equal to or less than 5 parts by mass with respect to 100 parts by mass of the entire radical polymerizable components in the composition (X), for example. As used herein, the “radical polymerizable component” refers to a component that produces radical polymerization reaction while the composition (X) is being heated and cured. The radical polymerizable component includes the compound (A) and the compound (B). If the composition (X) contains the reactive compound (D), the radical polymerizable component further includes the reactive compound (D) as well.

The composition (X) may contain appropriate additional components other than the above-described ones as long as the advantages of this embodiment are not significantly impaired. For example, the composition (X) may contain at least one component selected from the group consisting of, for example, flame retardants, organic radical compounds, defoaming agents such as silicone defoaming agents and acrylic acid ester defoaming agents, heat stabilizers, antistatic agents, ultraviolet absorbers, dyes, pigments, lubricants, and dispersants such as wetting dispersants.

The composition (X) may contain a solvent. That is to say, the composition (X) may contain a solvent and thereby be prepared as a resin varnish. This makes it easier to form the composition (X) into a sheet shape. The solvent preferably contains at least one component selected from the group consisting of an aliphatic hydrocarbon solvent, an aromatic hydrocarbon solvent, and a ketone solvent.

The composition (X) preferably contains no elastomers. If the composition (X) contains any elastomer, then the content of the elastomer is preferably adjusted to such a degree as to avoid causing a decline in the heat resistance of the cured product. In particular, the percentage of the elastomer with respect to 100 parts by mass in total of the compound (A) and the compound (B) (or the total of the compound (A), the compound (B), and the reactive compound (D) if the composition (X) contains the reactive compound (D)) is preferably equal to or less than 20 parts by mass.

The cured product of the composition (X) preferably has an elastic modulus equal to or greater than 0.2 GPa and equal to or less than 6 GPa. That is to say, the elastic modulus of the cured product of the composition (X) is preferably lowered to a value equal to or greater than 0.2 GPa and equal to or less than 6 GPa by reducing the elastic modulus of the cured product of the composition (X) according to this embodiment. Setting the elastic modulus at a value equal to or greater than 0.2 GPa enables reducing the chances of causing a decline in the machinability of the cured product, which is beneficial. Also, setting the elastic modulus at a value equal to or less than 6 GPa allows the insulating layer formed out of the composition (X) to have particularly good flexibility. Consequently, a flexible or bendable metal-clad laminate having an insulating layer formed out of the composition (X) or a flexible or bendable printed wiring board having an insulating layer formed out of the composition (X) may be obtained. The elastic modulus is more preferably equal to or greater than 1.0 GPa, and even more preferably equal to or greater than 2.0 GPa. Also, the elastic modulus is more preferably equal to or less than 5.5 GPa, and even more preferably equal to or less than 5 GPa. The contents of the compound (B2), the inorganic filler (C), and other components of the composition (X) are preferably set to achieve an elastic modulus falling within this preferred range.

A resin sheet, a sheet of metal foil with resin, a metal-clad laminate, and a printed wiring board, for example, may be each manufactured by using the composition (X).

The resin sheet according to this embodiment includes an uncured product or semi-cured product of the composition (X). As used herein, the “uncured product” refers to the composition (X) in Stage A state. That is to say, the “uncured product” herein refers to either the composition (X) itself or a product obtained by vaporizing a solvent from the composition (X) containing the solvent. On the other hand, the semi-cured product herein refers to the composition (X) in Stage B state, i.e., a product obtained by allowing the composition (X) to be cured incompletely, i.e., to the degree of not reaching a fully cured state (Stage C state).

The resin sheet may be used as a material for making a laminate and a printed wiring board. That is to say, the resin sheet may be used to make a laminate with an insulating layer including a cured product of the resin sheet (i.e., an insulating layer including a cured product of the composition (X)) and a printed wiring board with an insulating layer including a cured product of the resin sheet (i.e., an insulating layer including a cured product of the composition (X)).

To make a resin sheet, the composition (X) may be formed into a sheet shape by an application method, for example, and then heated to be dried or semi-cured. In this manner, a resin sheet including an uncured product or semi-cured product of the composition (X) is obtained. The heating temperature only needs to be high enough to dry the solvent included in the composition (X) and thereby semi-cure the resin component, and may be, for example, equal to or higher than 100° C. and equal to or lower than 160° C., and the heating duration may be, for example, equal to or longer than 1 minute and equal to or shorter than 5 minutes.

Alternatively, the resin sheet may also be a prepreg. In that case, the composition (X) is impregnated into a fibrous base member such as woven fabric or non-woven fabric and then heated to be dried or semi-cured. In this manner, a prepreg including the fibrous base member and the uncured or semi-cured product of the composition (X) impregnated into the fibrous base member may be obtained.

Heating and curing the resin sheet allows an insulating layer including a cured product of the composition (X) to be formed. The heating temperature may be, for example, equal to or higher than 160° C. and equal to or lower than 200° C. and is preferably equal to or higher than 180° C. and equal to or lower than 200° C. The heating duration may be, for example, equal to or longer than 30 minutes and equal to or shorter than 120 minutes and is preferably equal to or longer than 60 minutes and equal to or shorter than 120 minutes.

The resin sheet may be used as a bonding sheet for bonding a plurality of layers together. Specifically, the composition (X) may be applied onto a supporting film, for example, and formed into a sheet shape, and then dried or semi-cured, thus forming a resin sheet including an uncured or semi-cured product of the composition (X) on the supporting film. This resin sheet is attached onto a substrate and then the supporting film is peeled from the resin sheet. Subsequently, another substrate is attached onto the resin sheet. That is to say, the resin sheet is interposed between the two substrates. Subsequently, the resin sheet is heated to be cured, thereby forming an insulating layer. This allows the two substrates to be bonded together via this insulating layer.

The sheet of metal foil with resin according to this embodiment includes a sheet of metal foil and a resin layer laid on the sheet of metal foil. The resin layer includes an uncured product or semi-cured product of the composition (X). That is to say, the resin layer is formed out of a resin sheet made of the composition (X). In this case, the composition (X) is formed, by an application method, for example, into a sheet shape on the sheet of metal foil and then heated to be dried or semi-cured. In this manner, the resin layer may be formed on the sheet of metal foil. In this case, the condition for heating the composition (X) preferably includes, for example, a heating temperature equal to or higher than 100° C. and equal to or lower than 160° C. and a heating duration equal to or longer than 5 minutes and equal to or shorter than 10 minutes.

If a metal-clad laminate or a printed wiring board is formed based on the sheet of metal foil with resin, then an insulating layer is formed out of the resin layer. This may lower the dielectric constant and dielectric loss tangent of the insulating layer.

The sheet of metal foil may be a sheet of copper foil, for example. The sheet of metal foil may have a thickness equal to or greater than 2 μm and equal to or less than 105 μm, for example, and preferably has a thickness equal to or greater than 5 μm and equal to or less than 35 μm. The sheet of metal foil may be, for example, a sheet of copper foil which forms part of a sheet of copper foil having a thickness of 2 μm with a sheet of copper carrier foil having a thickness of 18 μm.

The resin layer may include a plurality of layers with mutually different compositions.

In that case, the plurality of layers may include a layer including an uncured or semi-cured product of the composition (X) and a layer including neither an uncured product of the composition (X) nor a semi-cured product of the composition (X). For example, the resin layer may include: a first resin layer stacked on a sheet of metal foil; and a second resin layer stacked on the first resin layer. The second resin layer may be the layer including an uncured or semi-cured product of the composition (X). In that case, the first resin layer may contain at least one component selected from the group consisting of, for example, a liquid crystal polymer resin, a polyimide resin, a polyamide imide resin, a fluorocarbon resin, and a polyphenylene ether resin.

A metal-clad laminate according to this embodiment includes an insulating layer and a sheet of metal foil laid on the insulating layer. The insulating layer contains a cured product of the composition (X). This allows the insulating layer of the metal-clad laminate to have its dielectric constant, dielectric loss tangent, and elastic modulus reduced and have its flexibility and heat resistance increased.

The metal-clad laminate may be formed out of the sheet of metal foil with resin described above. In that case, the sheet of metal foil of the metal-clad laminate may be formed out of the sheet of metal foil of the sheet of metal foil with resin and the insulating layer may be formed out of the resin layer of the sheet of metal foil with resin. The metal-clad laminate may include a plurality of sheets of metal foil and may include a plurality of insulating layers. If the metal-clad laminate includes a plurality of insulating layers, at least one of the plurality of insulating layers may contain the cured product of the composition (X).

A printed wiring board according to this embodiment includes an insulating layer and conductor wiring. The insulating layer contains the cured product of the composition (X). This allows the insulating layer of the printed wiring board to have its dielectric constant, dielectric loss tangent, and elastic modulus reduced and have its flexibility and heat resistance increased.

The metal-clad laminate may be formed out of the metal-clad laminate. In that case, the conductor wiring of the printed wiring board may be formed by subjecting the sheet of metal foil of the metal-clad laminate to an etching process, for example, and the insulating layer of the metal-clad laminate may be used as it is as the insulating layer of the printed wiring board. The printed wiring board may include a plurality of layers of conductor wiring and a plurality of insulating layers. If the printed wiring board includes a plurality of insulating layers, then at least one of the plurality of insulating layers may contain the cured product of the composition (X).

### (Recapitulation)

A thermosetting resin composition according to a first aspect contains: a maleimide compound (A) having at least two maleimide groups in one molecule; a compound (B) having, at either or both of terminals thereof, a substituent with an ethylenic unsaturated bond and having a polyphenylene ether skeleton; and an inorganic filler (C). The compound (B) includes a compound (B1) having a butadiene-derived structural unit.

This aspect contributes to reducing the elastic modulus of a cured product of the thermosetting resin composition and increasing the flexibility thereof and reduces the chances of causing a decline in the heat resistance of the cured product of the thermosetting resin composition.

In a second aspect, which may be implemented as in conjunction with the first aspect, the compound (B1) has a weight average molecular weight equal to or greater than 50,000 and equal to or less than 100,000.

In a third aspect, which may be implemented as in conjunction with the first or second aspect, the compound (B) further includes a compound (B2) having no butadiene-derived structural units.

In a fourth aspect, which may be implemented as in conjunction with any one of the first to third aspects, the inorganic filler (C) contains silica subjected to surface treatment with a surface treatment agent having a phenylamino group.

In a fifth aspect, which may be implemented as in conjunction with any one of the first to fourth aspects, the thermosetting resin composition further contains a reactive compound (D) having reactivity with the compound (A) and the compound (B).

In a sixth aspect, which may be implemented as in conjunction with any one of the first to fifth aspects, a cured product of the thermosetting resin composition has an elastic modulus equal to or greater than 0.2 GPa and equal to or less than 6 GPa.

A resin sheet according to a seventh aspect contains an uncured or semi-cured product of the thermosetting resin composition according to any one of the first to sixth aspects.

A sheet of metal foil with resin according to an eighth aspect includes a sheet of metal foil, and a resin layer laid on the sheet of metal foil. The resin layer contains an uncured or semi-cured product of the thermosetting resin composition according to any one of the first to sixth aspects.

A metal-clad laminate according to a ninth aspect includes: an insulating layer; and a sheet of metal foil laid on the insulating layer. The insulating layer contains a cured product of the thermosetting resin composition according to any one of the first to sixth aspects.

A printed wiring board according to a tenth aspect includes an insulating layer and conductor wiring. The insulating layer contains a cured product of the thermosetting resin composition according to any one of the first to sixth aspects.

### Examples

Next, more specific examples of this embodiment will be presented. Note that the examples to be described below are only examples of this embodiment and should not be construed as limiting.

### 1. Preparation of Composition

The components shown in the “Material Composition” column in Table 1 were dissolved in methyl ethyl ketone to prepare a composition having a solid content concentration of 80% by mass.

The details of the components shown in the “Material Composition” column in Table 1 are as follows:
Maleimide compound #1: maleimide oligomer. product number MIR3000, manufactured by Nippon Kayaku Co., Ltd., having two to four maleimide groups in one molecule and having a weight average molecular weight of 2000;
Maleimide compound #2: bismaleimide compound, product number BMI5100, manufactured by Daiwa Fine Chemicals Co., Ltd., having two maleimide groups in one molecule and having a molecular weight of 442;
Modified polyphenylene ether butadiene copolymer: compound having a substituent with an ethylenic unsaturated bond at either or both of its terminals and having a polyphenylene ether skeleton and a butadiene residue, product number BX660, manufactured by Nippon Kayaku Co., Ltd., having a weight average molecular weight of 50,000 to 100,000;
Modified polyphenylene ether: product number OPE-2St-1200, manufactured by Mitsubishi Gas Chemical Company Inc., having a weight average molecular weight of 1200;
Allyl compound #1: diallyl bisphenol A (DABPA);
Allyl compound #2: triallyl isocyanurate (TAIC);
Methacrylate compound: tricyclodecanedimethanol dimethacrylate (DCP);
Polymerization initiator: α,α′-di(t-butylperoxy) diisopropyl benzene, product name Perbutyl P, manufactured by NOF Corporation;
Inorganic filler #1: spherical silica surface-treated with vinylsilane, product number SC2300-SVJ, manufactured by Admatechs;
Inorganic filler #2: spherical silica surface-treated with phenylamino silane, product number SC2500-SXJ, manufactured by Admatechs;
Elastomer #1: styrene-ethylene-butylene-styrene block copolymer, product name Septon V9827, manufactured by Kuraray Co., Ltd.; and
Elastomer #2: polystyrene-hydrogenated (isoprene/butadiene)-polystyrene block copolymer, product name Septon 4033, manufactured by Kuraray Co., Ltd.

### 2. Evaluation Tests

### (1) Elastic Modulus

Using a comma coater and a dryer connected thereto, the composition was applied onto a sheet of copper foil having a thickness of 23 μm, and then heated to 120° C. for 2 minutes. In this manner, a semi-cured resin layer was formed to a thickness of 50 μm on the sheet of copper foil.

Two sheets of copper foil, each having a thickness of 23 μm, were arranged so that their resin layers faced each other. A metal-clad laminate was formed by hot-pressing these sheets of copper foil for 2 hours at a heating temperature of 220° C. and a pressing pressure of 2 Pa. This metal-clad laminate was subjected to an etching process to remove the sheets of copper foil from both sides, thereby making a sample formed out of a cured product of the resin and having a thickness of 100 μm.

The elastic modulus of this sample was measured by dynamic viscoelasticity measurement method under the conditions including a measurement frequency of 10 Hz, a temperature increase rate of 5° C./min, and a temperature range of 30-400° C.

### (2) Flexibility

Using a comma coater and a dryer connected thereto, the composition was applied onto a sheet of copper foil having a thickness of 23 μm, and then heated at 120° C. for 2 minutes. In this manner, a semi-cured resin layer was formed to a thickness of 50 μm on the sheet of copper foil. Two sheets of copper foil were arranged so that their resin layers faced each other. A metal-clad laminate was formed by hot-pressing these sheets of copper foil for 2 hours at a heating temperature of 220° C. and a pressing pressure of 2 MPa. This metal-clad laminate was subjected to an etching process to remove the sheets of copper foil from both sides, thereby making a sample formed out of a cured product of the resin and having a thickness of 100 μm.

This sample was observed to see if the cured product would have any cracks when wound around a rod having a diameter of 10 mm. When no cracks were recognized in the cured product, the sample was graded a “GO.” On the other hand, when any cracks were recognized there, the sample was graded a “NO-GO.”

### (3) Glass Transition Temperature (Tg)

Using a comma coater and a dryer connected thereto, the composition was applied onto a sheet of copper foil having a thickness of 23 μm, and then heated to 120° C. for 2 minutes. In this manner, a semi-cured resin layer was formed to a thickness of 50 μm on the sheet of copper foil.

Two sheets of copper foil, each having a thickness of 23 μm, were arranged so that their resin layers faced each other. A metal-clad laminate was formed by hot-pressing these sheets of copper foil for 2 hours at a heating temperature of 220° C. and a pressing pressure of 2 MPa. This metal-clad laminate was subjected to an etching process to remove the sheets of copper foil from both sides, thereby making a sample formed out of a cured product of the resin and having a thickness of 100 μm.

The glass transition temperature of this sample was measured by dynamic viscoelasticity measurement under the conditions including a measurement frequency of 10 Hz, a temperature increase rate of 5° C./min, and a temperature range of 30-400° C. In Comparative Examples 2 and 3, the addition of the elastomer inhibited the reaction to cause such a significant decrease in glass transition temperature that the glass transition temperature could not be measured.

### (4) Copper Foil Peel Strength

Using a comma coater and a dryer connected thereto, the composition was applied onto a sheet of copper foil having a thickness of 23 μm, and then heated to 120° C. for 2 minutes. In this manner, a semi-cured resin layer was formed to a thickness of 50 μm on the sheet of copper foil. Two sheets of copper foil were arranged so that their resin layers faced each other. A metal-clad laminate was formed by hot-pressing these sheets of copper foil for 2 hours at a heating temperature of 220° C. and a pressing pressure of 2 MPa. A sample was made by fixing this double-sided laminate onto a resin plate with a double-sided adhesive tape.

With respect to this sample, a 900 peel strength was measured between the sheets of copper foil and the cured product of the resin.

### (5) Relative Dielectric Constant and Dielectric Loss Tangent

Using a comma coater and a dryer connected thereto, the composition was applied onto a sheet of copper foil having a thickness of 23 μm, and then heated to 120° C. for 2 minutes. In this manner, a semi-cured resin layer was formed to a thickness of 50 μm on the sheet of copper foil. Two sheets of copper foil were arranged so that their resin layers faced each other. A metal-clad laminate was formed by hot-pressing these sheets of copper foil for 2 hours at a heating temperature of 220° C. and a pressing pressure of 2 MPa.

This metal-clad laminate was subjected to an etching process to remove the sheets of copper foil from both sides, thereby obtaining a test piece formed out of the cured product of the resin and having a thickness of 100 μm.

The relative dielectric constant and dielectric loss tangent of this test piece were measured at a test frequency of 10 GHz in compliance with the IPC TM-650 2.5.5.5 standard.

### (6) Coefficient of Linear Expansion

Using a comma coater and a dryer connected thereto, the composition was applied onto a sheet of copper foil having a thickness of 23 μm, and then heated to 120° C. for 2 minutes. In this manner, a semi-cured resin layer was formed to a thickness of 50 μm on the sheet of copper foil.

Two sheets of copper foil, each having a thickness of 23 μm, were arranged so that their resin layers faced each other. A metal-clad laminate was formed by hot-pressing these sheets of copper foil for 2 hours at a heating temperature of 220° C. and a pressing pressure of 2 MPa. This metal-clad laminate was subjected to an etching process to remove the sheets of copper foil from both sides, thereby making a sample formed out of a cured product of the resin and having a thickness of 100 μm.

The coefficient of linear expansion of this sample was measured in a direction perpendicular to the thickness direction by thermomechanical analysis method under the conditions including a temperature increase rate of 10° C./min, a tension of 98 mN, and a temperature range of 30-350° C.

TABLE 1

| | | Examples | | |
|---|---|---|---|---|
| | | 1 | 2 | 3 |
| Material | Maleimide | 25 | 30 | 0 |
| Composition | compound #1 | | | |
| (parts | Maleimide | 0 | 0 | 40 |
| by mass) | compound #2 | | | |
| | Modified | 20 | 10 | 10 |
| | polyphenylene | | | |
| | ether butadiene | | | |
| | copolymer | | | |
| | Modified | 35 | 35 | 25 |
| | polyphenylene | | | |
| | ether | | | |
| | Allyl | 0 | 7.5 | 7.5 |
| | compound #1 | | | |
| | Allyl | 10 | 10 | 10 |
| | compound #2 | | | |
| | Methacrylate | 15 | 7.5 | 7.5 |
| | compound | | | |
| | Polymerization | 0 | 2 | 2 |
| | initiator | | | |
| | Inorganic | 70 | 0 | 0 |
| | filler #1 | | | |
| | Inorganic | 50 | 150 | 350 |
| | filler #2 | | | |
| | Elastomer #1 | 0 | 0 | 0 |
| | Elastomer #2 | 0 | 0 | 0 |
| Evaluation | Elastic | 3.8 | 5.7 | 9 |
| | modulus (GPa) | | | |
| | Flexibility | GO | GO | GO |
| | Glass transition | 274 | 270 | 265 |
| | temperature | | | |
| | Tg (° C.) | | | |
| | Peel | 0.52 | 0.5 | 0.38 |
| | strength (N/m) | | | |
| | Relative | 2.73 | 2.85 | 3 |
| | dielectric | | | |
| | constant | | | |
| | Dielectric | 0.0029 | 0.0039 | 0.0032 |
| | loss tangent | | | |
| | Coefficient | 33 | 26 | 16 |
| | of linear | | | |
| | expansion | | | |
| | (ppm/K) | | | |

TABLE 2

| | | Comparative Examples | | | |
|---|---|---|---|---|---|
| | | 1 | 2 | 3 | 4 |
| Material | Maleimide | 35 | 25 | 25 | 0 |
| Composition | compound #1 | | | | |
| (parts | Maleimide | 0 | 0 | 0 | 45 |
| by mass) | compound #2 | | | | |
| | Modified | 0 | 0 | 0 | 0 |
| | polyphenylene | | | | |
| | ether butadiene | | | | |
| | copolymer | | | | |
| | Modified | 40 | 30 | 30 | 30 |
| | polyphenylene | | | | |
| | ether | | | | |
| | Allyl | 0 | 0 | 0 | 7.5 |
| | compound #1 | | | | |
| | Allyl | 10 | 10 | 10 | 10 |
| | compound #2 | | | | |
| | Methacrylate | 15 | 15 | 15 | 7.5 |
| | compound | | | | |
| | Polymerization | 0 | 0 | 0 | 2 |
| | initiator | | | | |
| | Inorganic | 70 | 70 | 70 | 0 |
| | filler #1 | | | | |
| | Inorganic | 50 | 50 | 50 | 350 |
| | filler #2 | | | | |
| | Elastomer #1 | 0 | 20 | 0 | 0 |
| | Elastomer #2 | 0 | 0 | 20 | 0 |
| Evaluation | Elastic | 8 | 1.4 | 1.1 | 15 |
| | modulus (GPa) | | | | |
| | Flexibility | NO-GO | GO | GO | NO-GO |
| | Glass transition | 270 | — | — | 263 |
| | temperature | | | | |
| | Tg (° C.) | | | | |
| | Peel | 0.49 | 0.43 | 0.38 | 0.38 |
| | strength (N/m) | | | | |
| | Relative | 2.74 | 2.66 | 2.57 | 3.04 |
| | dielectric | | | | |
| | constant | | | | |
| | Dielectric | 0.0031 | 0.0027 | 0.0025 | 0.0036 |
| | loss tangent | | | | |
| | Coefficient | 42 | 35 | 42 | 16 |
| | of linear | | | | |
| | expansion | | | | |
| | (ppm/K) | | | | |

1. A thermosetting resin composition containing:
a maleimide compound (A) having at least two maleimide groups in one molecule;
a compound (B) having, at either or both of terminals thereof, a substituent with an ethylenic unsaturated bond and having a polyphenylene ether skeleton; and
an inorganic filler (C),
the compound (B) including a compound (B1) having a butadiene-derived structural unit.

2. The thermosetting resin composition of claim 1, wherein
the compound (B1) has a weight average molecular weight equal to or greater than 50,000 and equal to or less than 100,000.

3. The thermosetting resin composition of claim 1, wherein
the compound (B) further includes a compound (B2) having no butadiene-derived structural units.

4. The thermosetting resin composition of claim 1, wherein
the inorganic filler (C) contains silica subjected to surface treatment with a surface treatment agent having a phenylamino group.

5. The thermosetting resin composition of claim 1, further containing a reactive compound (D) having reactivity with the compound (A) and the compound (B).

6. The thermosetting resin composition of claim 1, wherein
a cured product of the thermosetting resin composition has an elastic modulus equal to or greater than 0.2 GPa and equal to or less than 6 GPa.

7. A resin sheet containing an uncured or semi-cured product of the thermosetting resin composition of claim 1.

8. A sheet of metal foil with resin, comprising a sheet of metal foil, and a resin layer laid on the sheet of metal foil,
the resin layer containing an uncured or semi-cured product of the thermosetting resin composition of claim 1.

9. A metal-clad laminate comprising: an insulating layer; and a sheet of metal foil laid on the insulating layer,
the insulating layer containing a cured product of the thermosetting resin composition of claim 1.

10. A printed wiring board comprising an insulating layer and conductor wiring,
the insulating layer containing a cured product of the thermosetting resin composition of claim 1.
